(19) United States
(12) Patent Application Publication
(10) Pub. No.: US 2026/0016351 A1
(43) Pub. Date: Jan. 15, 2026

(54) Force detection foil sensor with direct force transducer

(71) Applicant: ADDSENSORS GMBH, Espelkamp (DE)

(72) Inventor: Eike Wilhelm Kottkamp, Lübbecke (DE)

(73) Assignee: ADDSENSORS GMBH, Espelkamp (DE)

(21) Appl. No.: 19/234,930

(22) Filed: Jun. 11, 2025

(30) Foreign Application Priority Data
Jun. 11, 2024 (DE) 10 2024 116 212.0
Dec. 4, 2024 (DE) 10 2024 135 994.3

(51) Int. Cl. G01L 1/22; B81B 3/00

(52) U.S. Cl. CPC G01L 1/2243; B81B 3/0021; G01L 1/2287; B81B 2201/0292; B81B 2203/0136; B81B 2203/0172; B81B 2203/04

(57) ABSTRACT

A foil sensor for force detection with direct force transducer, with a corresponding electrical contact line for detecting forces and force loads, wherein electrical signal can be derived from the foil sensor. At least two conductive electrodes are applied to the plastic film material which have a contacting area on the leads. On this surface of the plastic film material, a direct force transducer is applied, which absorbs the mechanical forces and deforms elastically when force is applied. A polymer nanocomposite material is also placed on this surface in such a way that the conductive electrodes are covered by the polymer nanocomposite material, which does not or only partially touches the direct force transducer, whereby a free area is formed between the material and transducer. The elastic material compression of the polymer nanocomposite can be detected by an impedance and/or electrical resistance measurement via the conductive electrodes.

The present invention relates to a foil-based force sensor with a direct force transducer and corresponding electrical contact conductors for detecting forces and loads. An electrical signal can be derived from the force sensor with direct force transducer.

Force sensors play a crucial role in a wide range of applications, from industrial automation to biomedical devices. These sensors measure forces and provide essential data for control, monitoring, and analysis of processes. Technological advancements in force sensors over the past decades have led to increased accuracy, reliability, and versatility.

Various types of force sensors exist, each based on different operating principles. Strain gauge-based sensors (SG) utilize the change in electrical resistance of a material when deformed. These sensors are widely used, particularly in industrial and mechanical engineering applications. They are highly sensitive and linear but are temperature-dependent and require calibration.

Piezoelectric sensors, which generate electrical charges when subjected to mechanical stress, are especially suitable for dynamic force measurements and vibration analyses.

They offer high sensitivity and fast response times but are less suitable for static force measurement.

Capacitive sensors measure the change in capacitance between two electrodes under mechanical load. They are commonly used in pressure measurement, medical devices, and robotics, offering high accuracy and low hysteresis, although they are sensitive to environmental influences.

Inductive sensors detect changes in the inductance of a coil due to displacement of a ferromagnetic core. They are used in position detection and the automotive industry.

These sensors are particularly robust and reliable but require more complex electronics and calibration.

Current trends in force sensor development include miniaturization and integration, especially through advances in microelectronics and MEMS (Micro-Electro-Mechanical Systems) technology. This enables the production of extremely small sensors used in medical and wearable devices. Wireless sensing has also gained importance, enabling real-time data transmission and remote monitoring, particularly advantageous in hard-to-access or hazardous environments.

New materials such as graphene and piezoresistive polymers offer improved sensitivity and flexibility and are increasingly used in flexible and stretchable sensors for robotics and wearable technologies. Moreover, integrating artificial intelligence (AI) and advanced data analytics tools improves data interpretation, enables predictive maintenance, and optimizes processes in real time.

Despite these advances, challenges remain, particularly regarding precise calibration and maintaining accuracy over the sensor's lifetime. Research focuses on self-calibrating systems and adaptive algorithms. Environmental influences such as temperature and humidity also pose challenges to sensor performance. Future developments aim to increase sensor robustness against such factors.

In summary, force sensing technology has advanced significantly in terms of accuracy, reliability, and range of applications. Ongoing research and development in materials, electronics, and data processing will continue to create new opportunities and improvements shaping the future of force measurement.

There is a growing need to further miniaturize and make force sensors more flexible.

Accordingly, the object of the present invention is to provide a flexible, low-profile force sensor evaluated via impedance and/or resistance measurement.

This objective is achieved by a foil-based force sensor with a direct force transducer according to claim 1 or further embodiments according to claims 2-10.

According to the invention, a foil-based force sensor with a direct force transducer comprises a composite element in which conductive electrode traces are applied to a polymer film. These are partially or entirely covered by a polymer nanocomposite, and a direct force transducer—preferably made of a polymer or metal—is mounted outside or partially above the electrode area and the nanocomposite area, leaving the electrical contacts accessible.

Such a composite allows higher forces to be detected, with the direct force transducer elastically deforming according to its material properties. This deformation causes a direct mechanical load on the polymer nanocomposite, which also undergoes elastic compression. The compression changes the electrical field and/or the electrical resistance measured between at least two conductive traces, preferably configured as an interdigital electrode structure (IDES).

By changing the material of the direct force transducer, the force measurement range can be adapted, enabling easy customization for different applications and thus broad applicability of the invention.

The polymer film (11) has at least two conductive electrodes (12), connected via a contact region (13). On the surface facing the electrodes, a direct force transducer (21) is mounted that absorbs mechanical forces and deforms elastically. The direct force transducer (21) does not fully cover the conductive electrodes (12) or the contact region (13).

A polymer nanocomposite (31) is also applied to the same side of the film, preferably covering the conductive electrodes (12) entirely or predominantly. The polymer nanocomposite (31) does not or only partially touch the direct force transducer (21), resulting in a free region (32) between the two components.

The top surfaces of the nanocomposite (31) and the direct force transducer (21) are aligned in a planar fashion. This planarity can also be achieved using a spacer (33), placed above the nanocomposite (31), made from a harder, less elastic material than the polymer nanocomposite (31).

According to the invention, when a flat force is applied to the top surface of the composite, both the polymer nanocomposite (31) and the direct force transducer (21) compress elastically. This deformation can be detected via impedance and/or resistance measurements between the conductive electrodes (12), with signal acquisition electronics connected to the contact region (13). Both the nanocomposite (31) and the transducer (21) deform into the free region (32).

The thicknesses of the polymer nanocomposite (31) and direct force transducer (21) can range from 50 μm to 1,000 μm, preferably from 100 μm to 400 μm.

The width and spacing of the interdigital electrode structures (12) on the film can range from 25 μm to 1,000 μm, preferably between 50 μm and 400 μm.

Another variant of the invention includes a force distribution plate (41) mounted on the planar surface of the nanocomposite (31) and transducer (21) to distribute local or partial forces evenly.

Another variant includes a protective film (51) that covers and encapsulates the nanocomposite (31) and transducer (21), being attached to the film (11).

Another variant places the direct force transducer (21) not only outside but also above the electrode area on the film (11), while the nanocomposite (31) is omitted in this region.

Further features of the invention arise from the attached claims, preferred embodiments, and drawings.

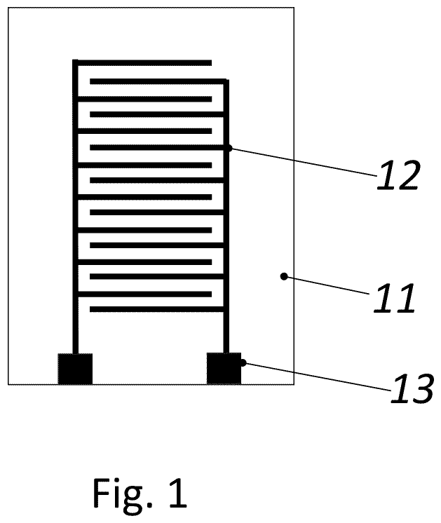

FIG. 1 shows a schematic structure of plastic film material (11) with applied conductive electrodes (12) and contact area (13)

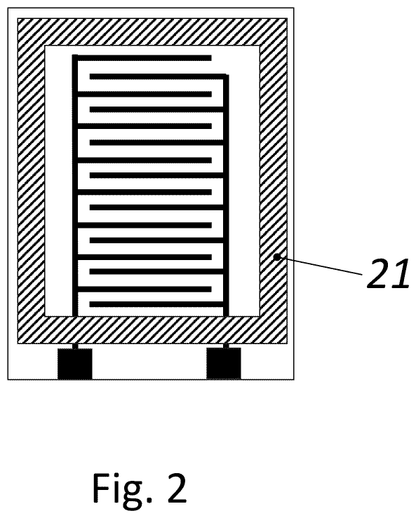

FIG. 2 shows a schematic structure of plastic film material (11) with applied conductive electrodes (12) and contact area (13), as well as a direct force transducer (21) attached to it.

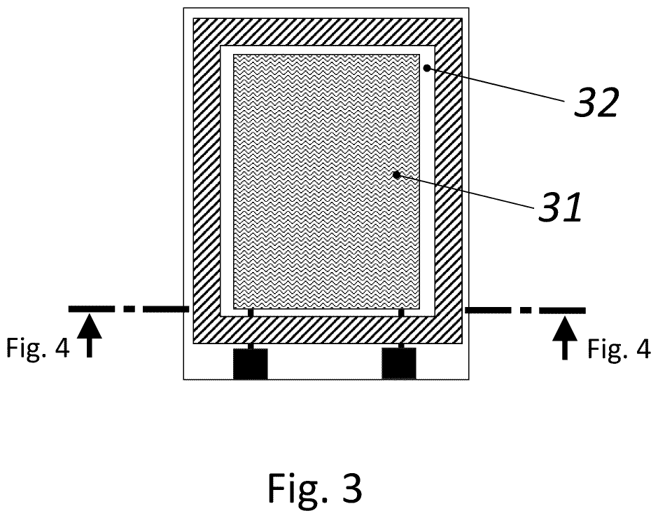

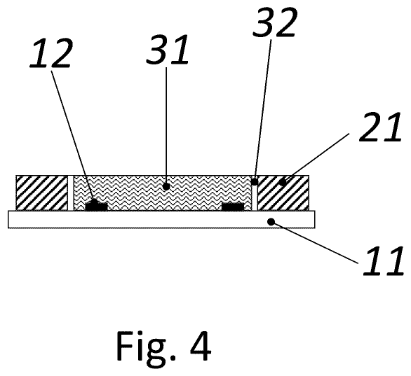

FIG. 3 shows a schematic structure of plastic film material (11) with applied conductive electrodes (12) and contact area (13), as well as an attached direct force transducer (21) and attached polymer nanocomposite material (31). FIG. 3 also contains section lines that refer to the sectional view in FIG. 4.

FIG. 4 shows a cross-sectional view of the invention according to claim 1.

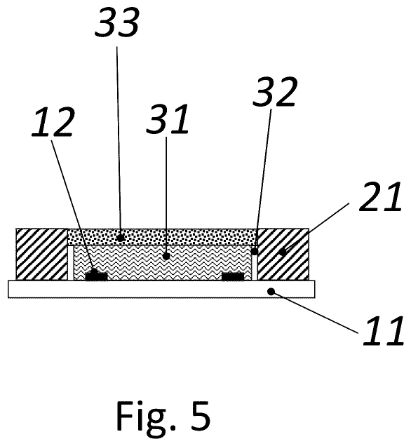

FIG. 5 shows a cross-sectional view of the invention according to claim 2, wherein a spacer (33) is introduced above the polymer nanocomposite material (31), which forms a planar surface for the direct force transducer (21).

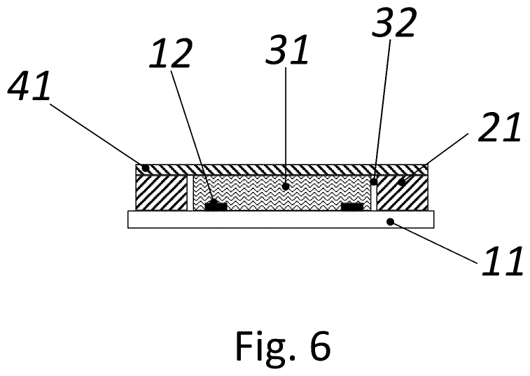

FIG. 6 shows a cross-sectional view of the invention's embodiment of the idea, wherein a force distribution plate (41) is inserted above the polymer nanocomposite material (31) and the direct force transducer (21), which generates a flat force effect on the polymer nanocomposite material (31) and the direct force transducer (21).

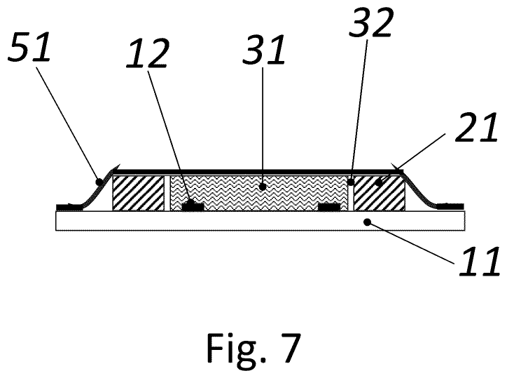

FIG. 7 shows a cross-sectional view of the invention's embodiment of the idea, wherein a protective film (51) completely covers and encloses the polymer nanocomposite material (31) and the direct force transducer (21).

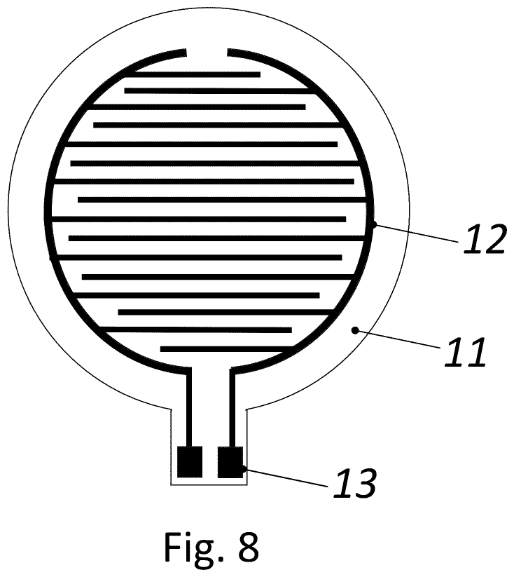

FIG. 8 shows another schematic structure and possible geometric configuration of plastic film material (11) with applied conductive electrodes (12) and contact area (13).

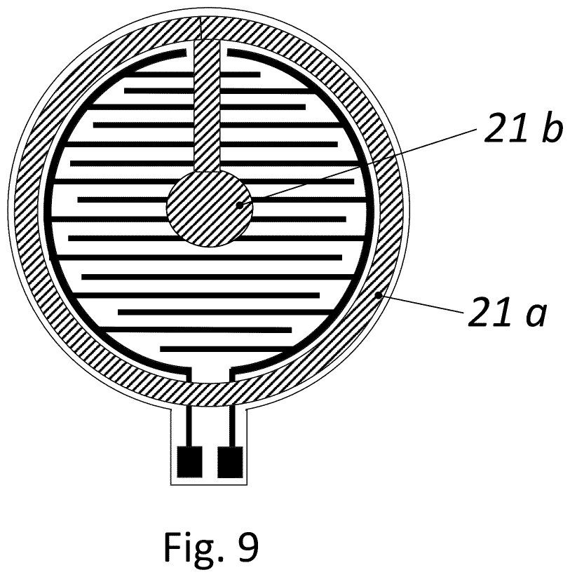

FIG. 9 shows another schematic structure and possible geometric configuration of plastic film material (11) with applied conductive electrodes (12) and contact area (13), as well as a direct force transducer (21) attached thereto, wherein the direct force transducer (21) extends in particular over the surface of the plastic film material (11) where the conductive electrodes (12) are arranged.

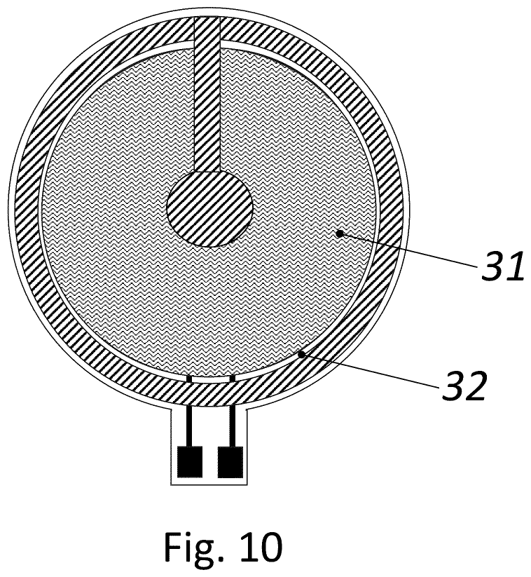

FIG. 10 shows another schematic structure and possible geometric configuration of plastic film material (11) with applied conductive electrodes (12) and contact area (13), as well as attached direct force transducers (21), wherein the direct force transducers (21) are arranged in particular on the surface of the plastic film material (11) where the conductive electrodes (12) are arranged, whereby the polymer nanocomposite material (31) is exposed in this area above the surface of the plastic film material (11) where the conductive electrodes (12) are arranged and the direct force transducer (21) is applied.

### PREFERRED EMBODIMENTS

1. Foil-based force sensor with at least one direct force transducer (21) arranged adjacent to or above the conductive electrodes (12) applied to a polymer film (11), where the space between is filled with at least one polymer nanocomposite (31).
2. As in 1, wherein a spacer (33) is added above the nanocomposite (31) to align flush with the transducer (21).
3. As in one of the above, wherein the direct force transducer (21) is affixed to the polymer film (11), preferably via adhesive or welding.
4. As in one of the above, wherein a force distribution plate (41) is applied above both the nanocomposite (31) and the transducer (21).
5. As in one of the above, wherein a protective film (51) fully covers and encapsulates both the nanocomposite (31) and the transducer (21).
6. As in one of the above, wherein the electrodes (12) form an interdigital electrode structure (IDES) made of conductive material such as copper, silver, carbon, or alloy, and the polymer film (11) is a flexible material such as PC, PA, PE, PEEK, PEI, PES, PP, PMMA, PS, PVC, PSU, PET, PEN, PI, FEP, or TPU.
7. As in one of the above, wherein the IDES has conductor widths and spacing of 25 μm to 1,000 μm, preferably 50 μm to 400 μm, with equal width and spacing.
8. As in one of the above, wherein the nanocomposite (31) has a thickness of 50 μm to 1,000 μm, preferably 100 μm to 400 μm.
9. As in one of the above, wherein the transducer (21) is made of metal, ceramic, or polymer but always has a higher modulus of elasticity than the nanocomposite (31).
10. Measuring device for detecting mechanical loads via impedance and/or resistance measurement, using a foil-based force sensor according to one of claims 1 to 9.

### LIST OF REFERENCE NUMERALS

11 Plastic film material
12 Conductive electrodes
13 Contacting area
21 Direct force transducer
21a Direct force transducer outside
21b Direct force transducer inside
31 Polymer nanocomposite material
32 Clearance area
33 Spacer
41 Force distribution plate
51 Protective film

1. A foil sensor with at least one direct force transducer arranged next to and or above the conductive electrodes, which are applied to a plastic foil material, the space between conductive electrodes, which are applied to a plastic foil material, and direct force transducer being filled with at least one polymer nanocomposite material.

2. The foil sensor according to claim 1, wherein a spacer is introduced above the polymer nanocomposite material, which forms a planar surface to the direct force transducer.

3. The foil sensor according to claim 1, wherein the direct force transducer is connected to the plastic foil material.

4. The foil sensor according to claim 1, wherein a force distribution plate is introduced over the polymer nanocomposite material and the direct force transducer, which generates a planar force effect on the polymer nanocomposite material and the direct force transducer.

5. The foil sensor according to claim 1, wherein a protective foil completely covers and encases the polymer nanocomposite material and the direct force transducer.

6. The foil sensor according to claim 1, wherein the conductive electrodes have an interdigital electrode structure (IDES) made of an electrically conductive material, and the plastic film material is a flexible polymer film.

7. The foil sensor according to claim 1, wherein the conductive electrodes have an interdigital electrode structure (IDES) made of an electrically conductive material, having a conductor track width of 25 μm to 1,000 μm, the ratio of conductor track and conductor track spacing being equal.

8. The foil sensor according to claim 1, wherein the polymer nanocomposite material has a material thickness of 50 μm to 1,000 μm.

9. The foil sensor according to claim 1, wherein the direct force transducer is made of a metal, ceramic or polymeric material, but always has a higher modulus of elasticity than the polymer nanocomposite material.

10. A measuring device for detecting force loads by means of an impedance and/or electrical resistance measurement using a foil sensor designed according to claim 1.
